(19) United States
(12) Patent Application Publication
(10) Pub. No.: US 2015/0221580 A1
(43) Pub. Date: Aug. 6, 2015

(54) SEMICONDUCTOR DEVICE AND MANUFACTURING METHOD OF THE SAME

(71) Applicant: KABUSHIKI KAISHA TOSHIBA, Tokyo (JP)

(72) Inventor: Takeshi FUKUI, Himeji Hyogo (JP)

(21) Appl. No.: 14/474,056

(22) Filed: Aug. 29, 2014

(30) Foreign Application Priority Data
Jan. 31, 2014 (JP) 2014-016883

(51) Int. Cl. H01L 23/495; H01L 23/31; H01L 23/00; H01L 21/56

(52) U.S. Cl. CPC H01L 23/49513; H01L 21/56; H01L 23/3107; H01L 24/83; H01L 24/32; H01L 24/27; H01L 2924/053; H01L 2924/01079; H01L 2924/01047; H01L 2924/01013; H01L 2924/01028; H01L 2224/29147; H01L 2224/83801; H01L 2224/32245; H01L 2224/32058

(57) ABSTRACT

A semiconductor device includes a semiconductor chip having a front surface electrode, a metal lead frame having a bed portion on a front surface of which the semiconductor chip is mounted and a post portion disposed separately from the bed portion, a resin sealing portion formed so as to cover the semiconductor chip, and a metal connector. The metal connector includes a chip junction portion joined to the front surface of the semiconductor chip, a post junction portion joined to a front surface of the post portion of the lead frame, and a connecting portion connecting the chip junction portion and the post junction portion. The chip junction portion has a thickness larger than a thickness of each of the post junction portion and the connecting portion. At least a part of the chip junction portion is exposed from a front surface of the sealing part.

### CROSS-REFERENCE TO RELATED APPLICATION

This application is based upon and claims the benefit of priority from Japanese Patent Application No. 2014-016883, filed Jan. 31, 2014, the entire contents of which are incorporated herein by reference.

### FIELD

Embodiments described herein relate generally to a semiconductor device and a manufacturing method of this device.

### BACKGROUND

A known semiconductor device includes a semiconductor chip, a lead frame and a connection terminal (i.e., wire and connector) connecting the semiconductor chip and the lead frame, and the whole of the semiconductor chip and the connection terminal are covered with insulating resin. According to this type of known semiconductor device, heat is dissipated from the semiconductor chip to the exterior of the device through the resin, which has lower heat conductivity than that of metal, and as a result sufficient dissipation of heat generated from the semiconductor chip during operation of the device is difficult to achieve. Particularly, in the case of a semiconductor device subject to flow of large current during use such as a type mounted on a vehicle or used in industrial fields, for example, the amount of heat generated from the semiconductor chip can cause various problems.

Moreover, according to the semiconductor device of the type including the semiconductor chip and the lead frame electrically connected with each other by the connector, problems of positional deviation of the chip and/or leads with respect to the lead frame can result from inclination or of the connector with respect to the underlying lead frame caused by the buoyant force of melted solder at the time of connection of the connector to the lead frame by solder reflow. The positional deviation and inclination of the connector may further produce problems such as generation of cracks, decrease in yield, separation of the connector from the resin, and deterioration of the reliability of the device in various aspects.

### DESCRIPTION OF THE DRAWINGS

FIGS. 1A and 1B are a plan, and sectional view, respectively, illustrating the general structure of a semiconductor device according to a first embodiment.

FIGS. 2A and 2B are a plan, and sectional view, respectively, illustrating the general structure of a semiconductor device according to another example of the first embodiment.

FIGS. 3A and 3B are a plan, and sectional view, respectively, illustrating the general structure of a semiconductor device according to a further example of the first embodiment.

FIGS. 4A and 4B are a plan, and sectional view, respectively, illustrating the general structure of a semiconductor device according to a still further example of the first embodiment.

FIGS. 5A and 5B are a plan, and sectional view, respectively, illustrating the general structure of a semiconductor device according to a still further example of the first embodiment.

FIGS. 6A through 6C illustrate manufacturing steps of the semiconductor device according to the first embodiment.

FIGS. 7A and 7B are a plan, and sectional view, respectively, illustrating the general structure of a semiconductor device according to a second embodiment.

### DETAILED DESCRIPTION

In general, according to one embodiment, there is provided a semiconductor device having an excellent heat dissipation property and an excellent low on-resistance property.

According to one embodiment, a semiconductor device includes a semiconductor chip, a metal lead frame, a resin sealing portion, and a metal connector electrically connecting the semiconductor chip and the lead frame. The semiconductor chip includes an electrode on the front surface thereof. The metal lead frame includes a bed portion, on a front surface of which the semiconductor chip is mounted, and a post portion disposed separately from the bed portion. The resin sealing portion is formed so as to cover the semiconductor chip. The metal connector includes a chip junction portion joined to the front surface of the semiconductor chip, a post junction portion joined to a front surface of the post portion of the lead frame, and a connecting portion connecting the chip junction portion and the post junction portion. The chip junction portion has a thickness larger than a thickness of each of the post junction portion and the connecting portion. At least a part of the chip junction portion is exposed from a front surface of the sealing part.

A semiconductor device and a manufacturing method of this device according to the embodiments are hereinafter described with reference to the drawings.

### First Embodiment

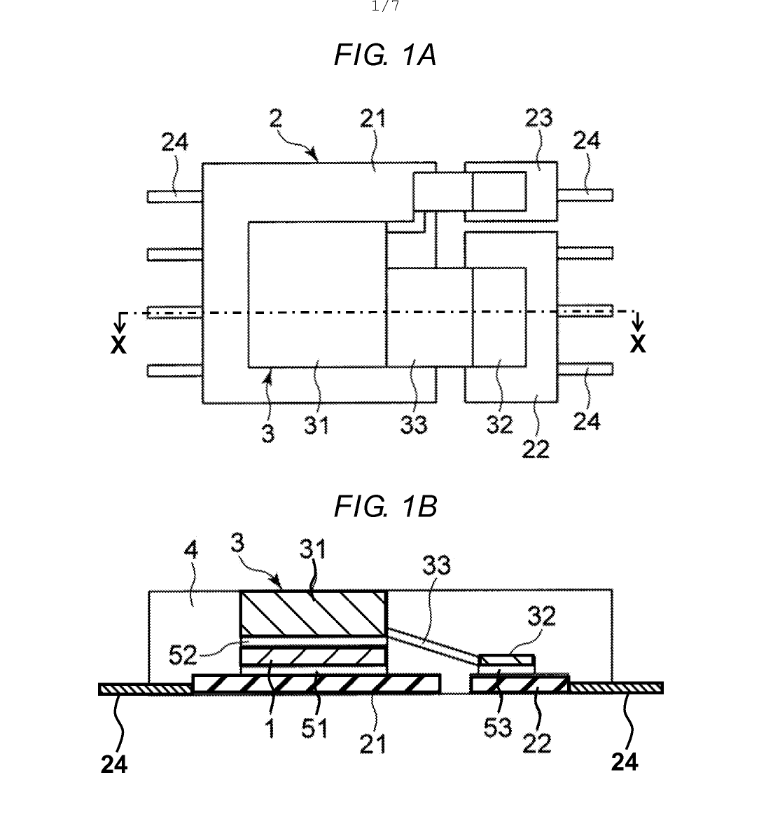

Initially, a semiconductor device according to a first embodiment is discussed with reference to FIGS. 1A through 6C. The semiconductor device according to this embodiment includes a semiconductor chip 1 and a lead frame 2 electrically connected with each other via a connector 3. The semiconductor chip 1 is sealed by a resin sealing portion 4.

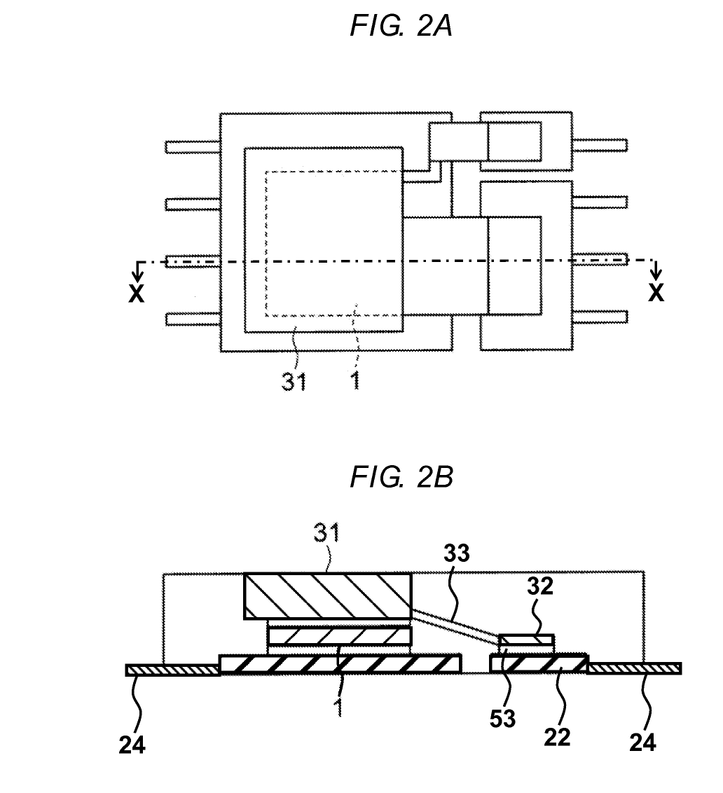

FIG. 1A is a plan view illustrating the semiconductor device according to this embodiment. In FIG. 1A, the sealing part 4 sealing the semiconductor chip 1 is omitted. FIG. 1B is a cross-sectional view taken along a line X-X in FIG. 1A. FIG. 1B shows the sealing part 4 sealing the semiconductor chip 1. This way of depiction, i.e., showing the sealing part 4 in the cross-sectional views but not showing the sealing part 4 in the plan views, is applicable to the following FIGS. 2A through 7B. As may be seen from FIGS. 1A and 1B, the semiconductor device according to this embodiment includes the semiconductor chip 1, the lead frame 2, the connector 3, the sealing part 4, and junctions 51, 52, and 53.

The semiconductor chip 1 may be configured as an Insulated Gate Bipolar Transistor (IGBT), a power Metal Oxide Semiconductor (MOS) transistor, a power Integrated Circuit (IC), and/or and other device structures. The semiconductor chip 1 further includes electrodes on each of the front surface and the rear surface of the semiconductor chip 1 for driving the components contained therein. The electrode provided on the front surface of the semiconductor chip 1 (hereinafter abbreviated as “front surface electrode”) is formed on the entire or apart of the front surface of the semiconductor chip 1. The front surface electrode is connected with a high-voltage side power source, for example. The electrode provided on the rear surface of the semiconductor chip 1 (hereinafter abbreviated as “rear surface electrode”) is formed on the entire or a part of the rear surface of the semiconductor chip 1. The rear surface electrode is connected with a low-voltage side power source, for example. In the following description, it is assumed that the front surface corresponds to the upper surface as viewed in the respective cross-sectional views, and that the rear surface corresponds to the lower surface as viewed in the respective cross-sectional views. The semiconductor chip 1 is joined to a bed portion 21 of the lead frame 2.

The lead frame 2 is a metal plate-shaped member to which the semiconductor chip 1 is fixed, and includes the bed portion 21, and separate post portions 22 and 23. As illustrated in FIG. 1A, each of the bed portion 21 and the post portions 22 and 23 have one or more outer leads 24 for connection between the semiconductor chip 1 and external wiring, through the bed 21 and post portions 22, 23. As illustrated in FIG. 1B, the rear surface of the bed portion 21 of the lead frame 2 is exposed, i.e., uncovered by, the sealing part 4.

The semiconductor chip 1 is mounted on the front surface of the bed portion 21 (die pad). The semiconductor chip 1 is joined to the front surface of the bed portion 21 via the junction 51. The junction 51 is formed by a conductive bond. This bond is made of solder or conductive resin containing silver, for example. The conductive junction 51 joins the front surface of the bed portion 21 and the rear surface of the semiconductor chip 1, thereby electrically connecting the bed portion 21 and the rear surface electrode of the semiconductor chip 1. This connection between the bed portion 21 and the rear surface electrode produces electric connection between external wiring (low-voltage side power source, for example) connected with an outer lead 24 of the bed portion 21 and the rear surface electrode of the semiconductor chip 1.

As noted above, the bed portion 21 is made of metal and therefore has higher heat conductivity than that of resin. Moreover, the rear surface of the bed portion 21 is not covered by the sealing part 4. According to this embodiment, heat generated from the semiconductor chip 1 is dissipated via the bed portion 21 thus constructed, wherefore the heat dissipation properties of the semiconductor device is improved.

The post portion 22 is electrically connected with the front surface electrode of the semiconductor chip 1 via the connector 3. The post portion 22 is connected with external wiring via an outer lead 24. The post portion 22 is disposed separately from the bed portion 21.

The post portion 23 is electrically connected with a control electrode of the semiconductor chip 1. This electric connection between the control electrode of the semiconductor chip 1 and the post portion 23 produces electric connection between the control electrode and external wiring (control circuit, for example) connected with the outer lead 24 of the post portion 23. The control electrode of the semiconductor chip 1 and the post portion 23 are electrically connected by a connection terminal such as a wire and a connector. The post portion 23 is disposed separately from the bed portion 21 and the post portion 22.

According to this structure, the bed portion 21, the post portion 22, and the post portion 23 separated from one another must be secured in a fixed relationship to one another, but electrically insulated from one another. For example, insulating resin may be embedded between the bed portion 21, the post portion 22, and the post portion 23 for purposes of electrical insulation and physical securement thereof.

The connector 3 is a metal plate-shaped member, which may be integrally formed of a single piece of metal, or assembled from multiple pieces of metal before being used as the connector, for electrically connecting the front surface electrode of the semiconductor chip 1 and the post portion 22. The electric connection between the front surface electrode of the semiconductor chip 1 and the post portion 22 via the connector 3 produces electric connection between the front surface electrode of the semiconductor chip 1 and external wiring (high-voltage side power source, for example) connected with an outer lead 24 of the post portion 22.

The connector 3 is made of metal material such as copper, nickel-plated copper, silver-plated copper, gold-plated copper, copper alloy, and aluminum. According to this structure, the connector 3 has lower on-resistance than that of a wire made of metal such as aluminum, gold, and copper, and increases the size of the connector and the surface area thereof, and thus the effectiveness, of bonding contact with the semiconductor chip 1 and with the sealing portion 4. The connector 3 includes a chip junction portion 31, a post junction portion 32, and a connecting portion 33.

The rear surface of the chip junction portion 31 is joined to the front surface of the semiconductor chip 1 via the junction 52. The junction 52 is formed by a conductive bonding material made of solder or conductive resin containing silver, for example. The junction between the chip junction portion 31 and the front surface of the semiconductor chip 1 by the conductive junction 52 produces electric connections between the chip junction portion 31 and the front surface electrode of the semiconductor chip 1.

As illustrated in FIGS. 1A and 1B, the chip junction portion 31 is so disposed as to cover the entirety of, or a part of, the front surface of the semiconductor chip 1, and has a thickness larger than the thickness of each of the post junction portion 32 and the connecting portion 33 so as to increase the surface area of the chip junction portion 31. At least a part of the front surface of the chip junction portion 31 extends through and is thus exposed to the outside of the packaged device through the sealing part 4.

As discussed above, the chip junction portion 31 made of metal has higher heat conductivity than that of resin. Moreover, the chip junction portion 31 has a larger thickness, and thus has a larger surface area, than the remaining portions of connector 3. Furthermore, the front surface of the chip junction portion 31 is exposed to ambient conditions, i.e., the environment around the packaged device which may include a heat sink, through the sealing part 4. According to this embodiment, heat generated from the semiconductor chip 1 is dissipated through the chip junction portion 31 through the side walls thereof into the adjacent resin and directly to the exterior environment of the packaged device, wherefore the heat dissipation property of the semiconductor device improves.

As illustrated in FIGS. 2A and 2B wherein the perimeter of the encapsulated semiconductor chip 1 is shown in phantom lines in FIG. 2A, the cross section of the chip junction portion 31 may be larger than the front surface of the semiconductor chip 1. According to this structure, the surface area of the chip junction portion 31 exposed through the resin 4 is further increased compared to the surface of the semiconductor chip 1, whereby the heat dissipation property of the semiconductor device is further improved.

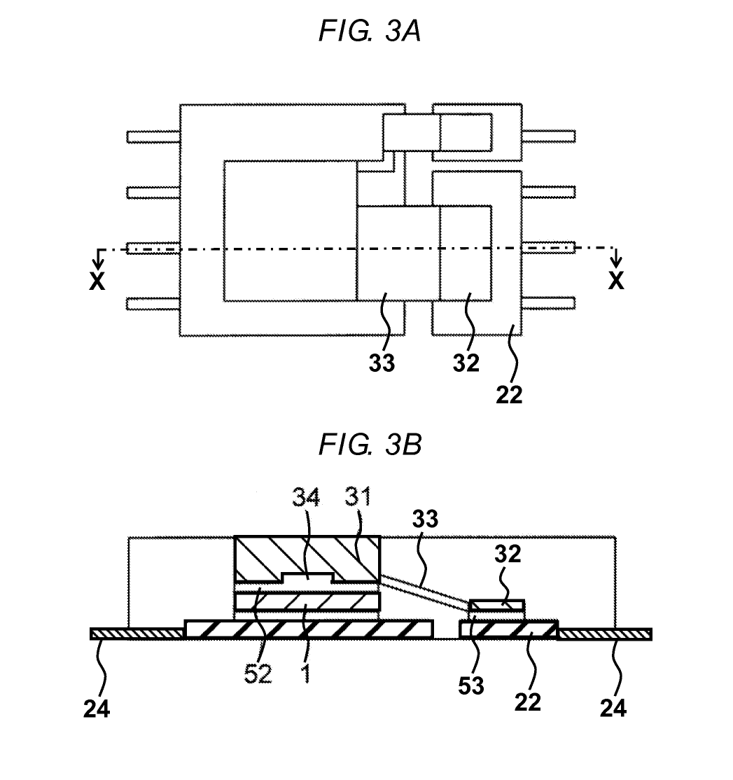

The thickness of a central part of the chip junction portion 31 (i.e., the span from the connection part 52 side to the exposed side thereof) may be made smaller than the thickness of the outer periphery thereof. For example, as illustrated in FIGS. 3A and 3B, a recess 34 may be formed in a central part of the chip junction portion 31 on the rear surface side to reduce the thickness of a central part of the chip junction portion 31. As shown in phantom in FIG. 3A, this recess 34 may not extend to the four perimeter walls of the chip junction portion 31 This structure reduces warping of the chip junction portion 31 produced at the time of heat based operations used to complete the formation of the final packaged device (such as reflow and resin molding described below). The reduction of warping improves the flatness of the semiconductor device, reduces cracks in the solder joints of the device, or other problems, and thus increases the reliability of the semiconductor device.

The rear surface of the post junction portion 32 is joined to the front surface of the post portion 22 of the lead frame 2 via the junction 53. The junction 53 is formed by a conductive bond made of solder or conductive resin material containing silver, for example. The junction between the post junction portion 32 and the post portion 22 via the conductive junction 53 produces electric connection between the post junction portion 32 and the post portion 22. The post junction portion 32 is so disposed as to cover the entire or a part of the front surface of the post portion 22.

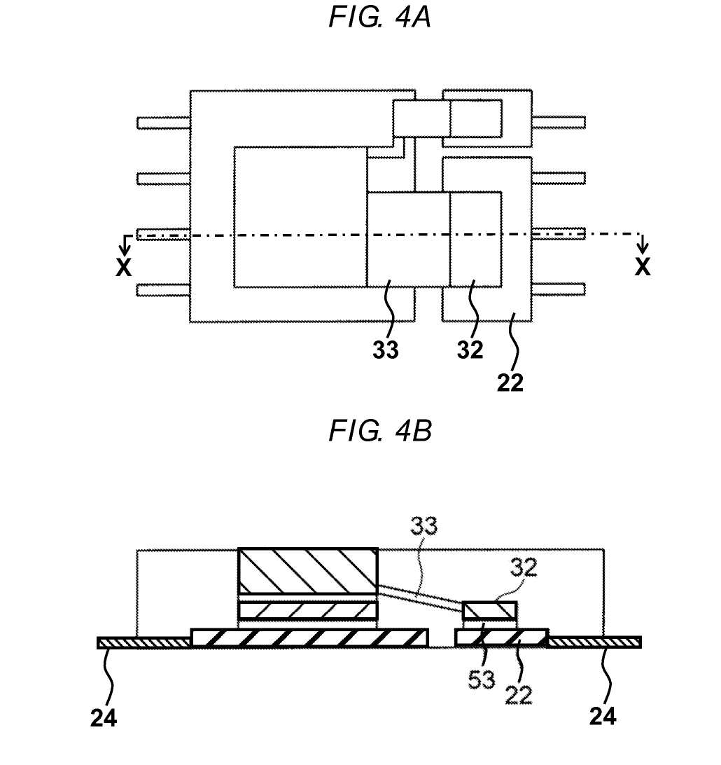

The connecting portion 33 is a portion connecting the chip junction portion 31 and the post junction portion 32. The connecting portion 33 may have an arbitrary shape capable of connecting the chip junction portion 31 and the post junction portion 32. For example, as illustrated in FIGS. 4A and 4B, in contrast to the structure thereof shown in FIGS. 1 to 3 the connecting portion 33 has a smaller thickness than that of the post junction portion 32, and connects with the post junction portion 32 in such a manner as to produce a step between the rear surface of the connecting portion 33 and the rear surface of the post junction portion 32. According to this structure, the melted bond material reaches the stepped area at the time of reflow (described below) and joins the post junction portion 32. Thus, the joining strength of the post junction portion 32 is improved.

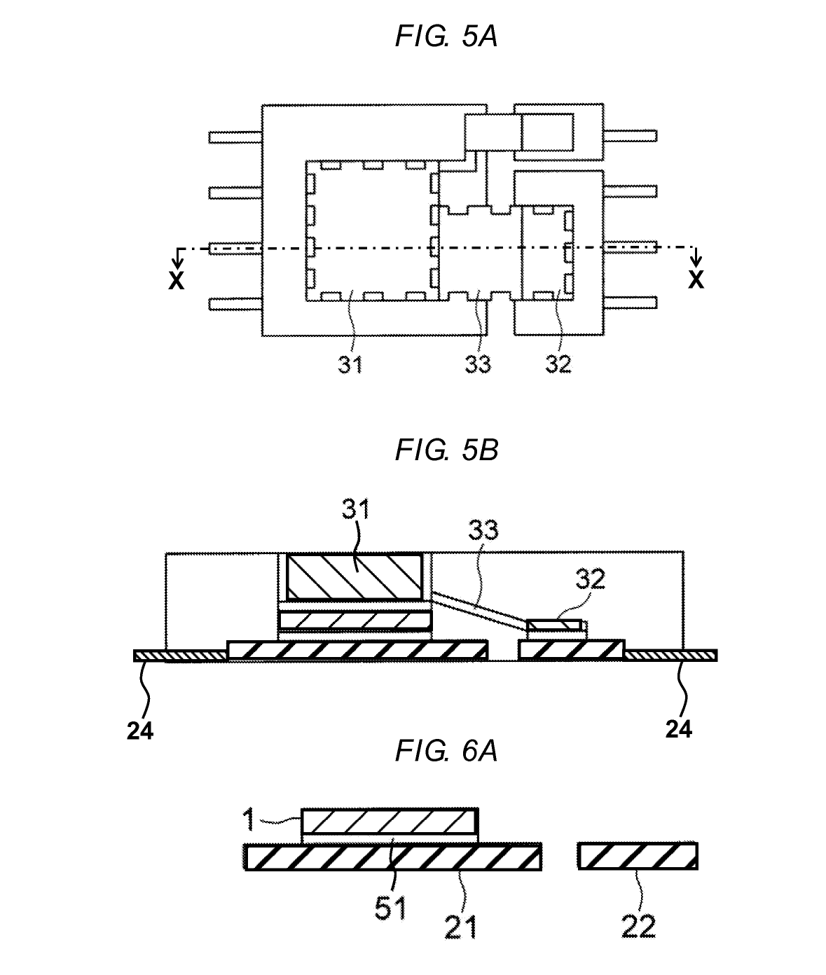

As illustrated in FIGS. 5A and 5B, concavities and convexities may be formed at least in apart of the side surface of the connector 3 by knurling or other methods. The concavities and convexities, i.e., scallops or slots, formed in the side surface of the connector 3 increase the surface area of contact between the connector 3 and the sealing part 4 by an anchoring effect, thereby improving the reliability of the semiconductor device in view of moisture resistance and temperature shock resistance.

The sealing part 4 is formed so as to cover the whole of the semiconductor chip 1 for protection of the semiconductor chip 1 from external forces and the outside air and formation of a housing of the semiconductor device. The sealing part 4 is made of insulating resin and formed in such a configuration as to allow exposure of the chip junction portion 31 of the connector 3 through the front surface of the sealing part 4, exposure of the lead frame 2 through the rear surface of the sealing part 4, and projection of the outer leads 24 through the side surface of the sealing part 4.

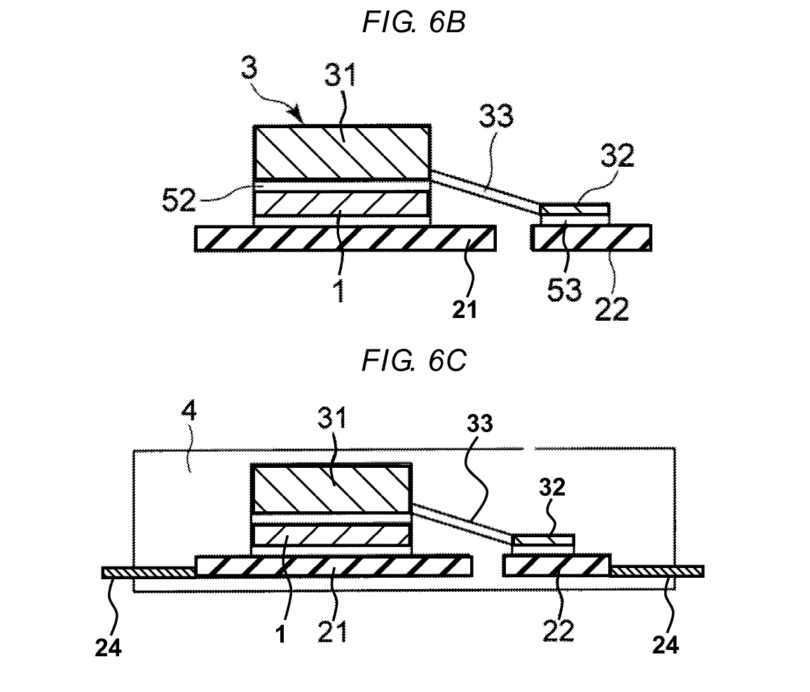

A manufacturing method of the semiconductor device according to this embodiment is now explained with reference to FIGS. 6A through 6C. FIGS. 6A through 6C illustrate the manufacturing method of the semiconductor device according to this embodiment, showing cross sections of the semiconductor device in respective steps.

Initially, an electrically conductive bonding material such as solder paste or a resin paste containing silver is applied to a predetermined position on the front surface of the bed portion 21 of the lead frame 2, and the semiconductor chip 1 is mounted on this bonding material. Then, the semiconductor chip 1 is joined to the bed portion 21 by reflowing the bonding material. More specifically, the bonding material is heated to its flow or melting temperature, with the semiconductor chip 1 mounted thereon. After melting of the bonding material, the bonding material is solidified by removing the heat and the bonding material cools and solidifies. As a result, the junction 51 is formed and joins the semiconductor chip 1 to the front surface of the bed portion 21 (see FIG. 6A).

In the next step, a bonding material such as solder paste or a resin containing silver is applied to a predetermined position on the front surface of the semiconductor chip 1 and a predetermined position on the front surface of the post portion 22 of the lead frame 2, and the connector 3 is mounted on this bonding material. Then, the connector 3 is joined to the semiconductor chip 1 by reflow of the bonding material. More specifically, the bonding material is heated with the connector 3 mounted thereon, and melted in this condition. After melting, the bonding material is solidified by removing the heat therefrom. As a result, the junctions 52 and 53 are formed as junctions for joining the chip junction portion 31 to the front surface of the semiconductor chip 1, and a junction for joining the post junction portion 32 to the post portion 22, respectively. Simultaneously, therebefore or thereafter, the control electrode of the semiconductor chip 1 and the post portion 23 are electrically connected by a connection terminal such as a wire and a connector.

In the next step, the semiconductor device configured as shown in FIG. 6B is introduced into a metal mold for resin molding. More specifically, the semiconductor chip 1 is sealed by insulating resin in such a manner that the whole of the semiconductor chip 1 may be covered by the resin (see FIG. 6C). In FIG. 6C, the entirety of the connector 3, and the bed portion 21 and post portions 22 and 23 of the lead frame 2 are covered by the sealing part 4, while the outer leads 24 of the lead frame 2 project through the side surface of the sealing part 4.

The front surface and the rear surface of the sealing part 4 thus formed are polished by a CMP (Chemical Mechanical Polishing) method, for example, to produce the semiconductor device of this embodiment shown in FIGS. 1A and 1B. The front surface of the sealing part 4 is polished until at least a part of the front surface of the chip junction portion 31 of the connector 3 is exposed therethrough, while the rear surface of the sealing part 4 is polished until at least a part of the rear surface of the bed portion 21 of the lead frame 2 is exposed therethrough.

This polishing of the front surface and the rear surface of the sealing part 4 after resin molding improves the flatness of the sealing part 4, and reduces stresses applied to the front surface side and rear surface side of the sealing part 4. Accordingly, the reliability of the semiconductor device is increased.

It is preferable that the polishing speed of the sealing part 4 is varied after the front surface of the chip junction portion 31 (bed portion 21) is exposed through the sealing part 4. For example, the sealing part 4 is polished at a first polishing speed until the chip junction portion 31 (bed portion 21) is exposed through the sealing part 4. After the chip junction portion 31 (bed portion 21) is exposed through the sealing part 4, the sealing part 4 is polished at a second polishing speed lower than the first polishing speed. After polishing at the second polishing speed, the polishing speed is set to zero for further polishing.

These changes of the polishing speed shorten the polishing time, reduce scratching and roughness of the front surface (rear surface) of the resulting packaged semiconductor, and lower the possibility of corner pitching of the sealing part 4 and separation of the sealing part resin from the chip junction portion 31. Accordingly, yield of packaged semiconductor devices, based on the external appearance thereof, improves.

According to this embodiment, as understood from the above description, heat generated from the semiconductor chip 1 is dissipated via the chip junction portion 31 of the connector 3. The chip junction portion 31 is a component having a large thickness for obtaining a large surface area, and made of metal having high heat conductivity. The front surface of the chip junction portion 31 is exposed to the ambient conditions around the package, such as air or a heat sink, through the sealing part 4. Moreover, heat generated from the semiconductor chip 1 is dissipated via the bed portion 21 of the lead frame 2. The bed portion 21 is a component made of metal having high heat conductivity, and the rear surface of the bed portion 21 is likewise exposed to the ambient conditions around the device through the sealing part 4. The semiconductor device according to this embodiment thus constructed achieves excellent heat dissipation property.

Accordingly, the semiconductor device in this embodiment is suited for use as a power module provided with IGBT, power MOS transistor, power IC, and other devices which require high heat dissipation properties.

The semiconductor device may include a plurality of semiconductor chips. For example, the semiconductor device may contain a high-voltage side semiconductor chip and a low-voltage side semiconductor chip connected by the connector 3 to have applicability to an inverter or the like.

A heat sink may be equipped on the chip junction portion 31 of the connector 3. The chip junction portion 31 exposed through the front surface of the sealing part 4 is capable of coming into direct contact with the heat sink. According to this structure, the heat dissipation property of the semiconductor device is further improved.

In the manufacturing method of the semiconductor device according to this embodiment, reflow executed after the step of applying the bonding material to the bed portion 21 of the lead frame 2 may be omitted. In this case, the omitted reflow may be carried out simultaneously with the reflow for joining the connector 3 to the post portion 22.

In the manufacturing method of the semiconductor device according to this embodiment, at least either one of the front surface of the chip junction portion 31 and the rear surface of the bed portion 21 may be left exposed during the resin molding step so as to avoid covering thereof by the sealing part 4. This structure eliminates, reduces or simplifies the foregoing polishing steps.

### Second Embodiment

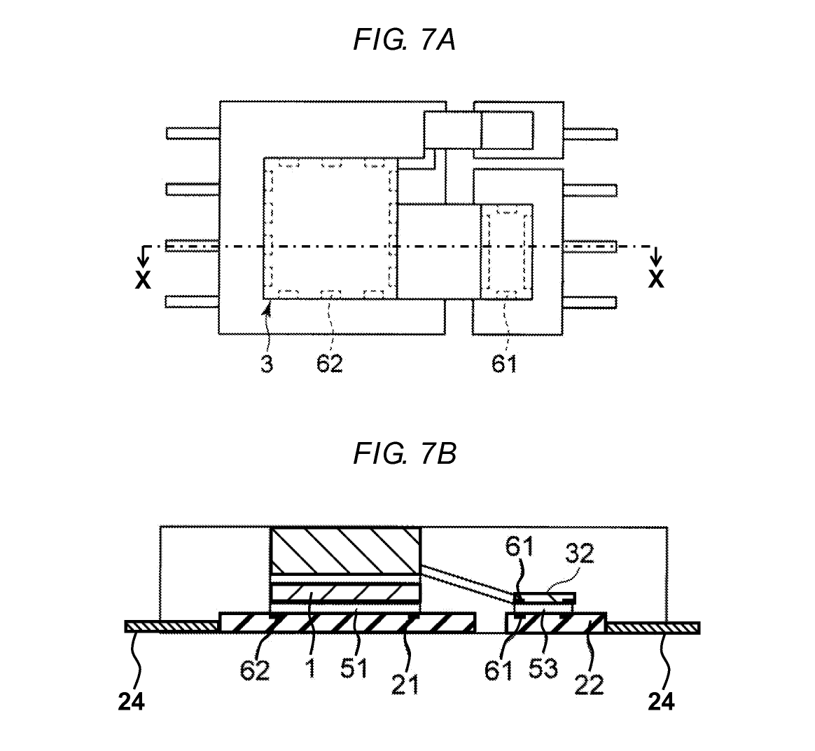

A semiconductor device according to a second embodiment is hereinafter described with reference to FIGS. 7A and 7B. According to the semiconductor device in this embodiment, a limited wetting portion 61 is provided in a part of the outer periphery of the junction surface between the post portion 22 of the lead frame 2 and the post junction portion 32 of the connector 3. Other points in the structure and the manufacturing method in this embodiment are similar to the corresponding points in the first embodiment, and therefore are not repeatedly discussed herein.

The limited wetting portion 61 is an area processed such that the wettability of the melted bond material becomes lower (i.e., the contact angle becomes smaller). For example, the limited wetting portion 61 is formed by applying laser beams to the front surface of the post portion 22 of the lead frame 2 and the rear surface of the post junction portion 32 of the connector 3 in air or an oxygen environment. An oxide film is thus produced in the area processed by the laser beams and has lower wettability than that of the area around the processed area, and therefore provides the function of the limited wetting portion 61.

For example, as illustrated in FIG. 7A, the limited wetting portion 61 is linearly formed along each of the long sides and short sides of the junction surface between the post portion 22 and the post junction portion 32. The limited wetting portion 61 thus formed prevents flow of the melted bond material to the outside of the junction surface, i.e., out from between the post portion 22—junction portion 32 interface region, at the time of reflow of the bonding material. The width, i.e., the extent of the limited wetting portion extending inwardly from the sides of the post portion 22 and junction portion 32, of the limited wetting portion 61 necessary for preventing flow of the melted bond material varies according to the particle diameter and flow characteristics of the melted bond material. For example, it is preferable that the width of the limited wetting portion 61 is 30 μm or larger. The width of the limited wetting portion 61 in the range of 30 μm or larger is sufficient for preventing flow of the bonding material to the outside of the junction surface between the post portion 22 and junction portion 32 even when the bonding material has high wettability.

It is preferable that the limited wetting portion 61, which is linearly formed along the long sides and short sides of the junction surface, is not provided at the corners of the junction surface. The absence of the limited wetting portion 61 at the corners of the junction surface allows discharge of the volume of voids (air or gas bubbles) contained in the bonding material to the outside of the junction surface from the corners. In consideration of the design of the post portion 22—junction portion 32 interface, when a Sn-base solder is used, the short side of the post portion 22—junction portion 32 interface is selected such that the diameter or width of the voids contained in the solder is smaller than 10% of the short side of the post portion 22—junction portion 32 interface. Accordingly, to ensure discharge of the voids having this size, it is preferable that the length of each corner is 10% or larger of the length of the short side of the junction surface, for example. The design including the length and position of the limited wetting portion 61 is selected in accordance with the voltage characteristics and area of the junction surface.

According to this embodiment, the position and area of the junction surface wet by the melted bond material at the time of reflow for joining the post portion 22 and the post junction portion 32 is limited by the limited wetting portions 61. This structure prevents deviation of the junction position of the post junction portion 32, i.e., because the bonding material upon reflow is significantly constrained by the limited wetting portions, the position of the junction portion 32 bonded to the post portion 22 does not significantly vary from device to device, and also reduces variation in the thickness of the junction 53 formed at the post portion 22—junction portion 32 interface, and therefore achieves connection of the post junction portion 32 without producing inclination of the connector 3. Accordingly, problems such as generation of cracks in the connector, junction, or interface of the junction to the post portion 22 and junction portion 32, and lowering of the reliability of the device, may decrease.

When a excessive bonding material is applied to the front surface of the post portion 22, or when voids (bubbles) are contained in the bonding material, the excessive bonding material or voids are discharged to the outside of the junction surface through the area where the limited wetting portion 61 is not formed (i.e., the corners). Accordingly, this structure prevents positional deviation or inclination of the connector 3 caused by the inappropriate amount of the applied bond or voids contained in the bond.

According to this embodiment, the limited wetting portion 61 maybe provided only either one of the front surface of the post portion 22 and the rear surface of the post junction portion 32. In a further example, a limited wetting portion 62 may be provided on the front surface of the bed portion 21 of the lead frame 2. In this case, as illustrated in FIG. 7A, the limited wetting portion 62 is formed in a part of the outer periphery of the junction surface between the rear surface of the semiconductor chip 1 and the front surface of the bed portion 21 of the lead frame 2. This structure prevents deviation of the junction position and inclination of the semiconductor chip 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device, comprising:
a semiconductor chip including a front surface electrode;
a metal lead frame including a bed portion, on a front surface of which the semiconductor chip is mounted, and a post portion disposed separately from the bed portion;
a resin sealing portion formed so as to cover the semiconductor chip; and
a metal connector including a chip junction portion joined to the front surface of the semiconductor chip, a post junction portion joined to a front surface of the post portion of the lead frame, and a connecting portion connecting the chip junction portion and the post junction portion,
wherein
the chip junction portion has a thickness larger than a thickness of each of the post junction portion and the connecting portion, and
at least a part of the chip junction portion is exposed through a front surface of the sealing part.

2. The device according to claim 1, wherein
a limited wetting portion preventing wetting of a melted bonding material is formed in a part of the outer periphery of a junction surface between the post portion of the lead frame and the post junction portion of the connector.

3. The device according to claim 2, wherein
the limited wetting portion is an oxide film.

4. The device according to claim 1, wherein
concavities and convexities are formed in at least a part of a side surface of the connector.

5. The device according to claim 1, wherein
at least a part of the chip junction portion of the connector is larger than the front surface of the semiconductor chip.

6. The device according to claim 1, wherein a central part of the chip junction portion of the connector is thinner than the thickness of the chip junction portion adjacent to the outer periphery thereof.

7. The device according to claim 1, wherein
the connector is made of copper, nickel-plated copper, silver-plated copper, gold-plated copper, copper alloy, or aluminum.

8. The device according to claim 1, wherein the post junction portion of the metal connector is thicker than the connection portion of the metal connector.

9. A manufacturing method for a semiconductor device, comprising:
providing a lead frame comprising a bed portion and a post portion;
joining a semiconductor chip having a front surface electrode to a front surface of the bed portion of the lead frame;
applying a bonding material to a front surface of the semiconductor chip and a front surface of the post portion of the lead frame, the post portion being disposed separately from the bed portion;
joining a metal connector to a front surface of the semiconductor chip and a front surface of the post portion of the lead frame via the bonding material, wherein the medal connector includes a chip junction portion joined to the front surface of the semiconductor chip, a post junction portion joined to a front surface of the post portion of the lead frame, and a connecting portion connecting the chip junction portion and the post junction portion, the chip junction portion having a thickness larger than a thickness of each of the post junction portion and the connecting portion;
sealing the semiconductor chip and the connector with resin to cover the semiconductor chip and the connector; and
polishing a front surface of the resin until a front surface of the chip junction portion of the connector is exposed.

10. The method according to claim 9, wherein
a polishing speed is varied before or after the front surface of the chip junction portion of the connector is exposed through the front surface of the resin.

11. The method according to claim 9, further including the step of polishing the back surface of the resin until the bed surface of the lead frame is exposed through the resin.

12. The method of claim 9, further including the step of, prior to joining the post junction portion of the metal connector to a front surface of the post portion of the lead frame, forming a limited wettability portion on a portion of at least one of the post junction portion or post portion exposed to a bonding material upon the reflow thereof.

13. The method according to claim 9, wherein the post junction portion is thicker than the connecting portion.

14. The method according to claim 9, wherein prior to the step of joining a semiconductor chip having a front surface electrode to a front surface of the bed portion of the lead frame;, forming a limited wettability portion on a portion of the front surface of the bed portion.

15. The method according to claim 9, wherein the metal connector is joined to the front surface of the semiconductor chip and the front surface of the post portion of the lead frame concurrently.

16. A packaged semiconductor device, comprising:
a lead frame having at least a bed portion and a post portion, each of the bed portion and post portions including at least one lead extending therefrom, the bed portion including a fist side and a second side;
a semiconductor device chip having a first side and a second side, the first side thereof electrically and physically connected to the first side of the bed portion;
a connector electrically connecting the second side of the semiconductor chip to the post portion of the lead frame, the connector having an integrally formed first portion electrically and physically connected to the second side of the semiconductor chip, a second portion physically and electrically connected to the post portion, and a connecting portion connecting the first portion and second portion, the first portion thicker than the second portion and the connecting portion; and
a sealing portion enclosing the semiconductor device.

17. The semiconductor device of claim 16, wherein the first portion of the connector extends from the second surface of the semiconductor chip to at least the adjacent outer surface of the sealing portion.

18. The semiconductor device of claim 16, wherein at least a portion of the second side of the bed portion is not covered by the sealing portion.

19. The semiconductor device of claim 16, wherein the second portion of the connector is thicker than the connecting portion of the connector.

20. The semiconductor device of claim 16, further including solder disposed between, and electrically and physically connecting, the first portion of the connector and the second side of the semiconductor chip.
